(19) United States
(12) Patent Application Publication
(10) Pub. No.: US 2026/0269839 A1
(43) Pub. Date: Sep. 10, 2026

(54) Multiplying digital-to-analog converter

(71) Applicant: REALTEK SEMICONDUCTOR CORPORATION, HSINCHU (TW)

(72) Inventor: SHIH-HSIUNG HUANG, HSINCHU (TW)

(21) Appl. No.: 19/465,137

(22) Filed: Jan. 30, 2026

(30) Foreign Application Priority Data
Feb. 19, 2025 (TW) 114106151

(51) Int. Cl. H03M 1/66

(52) U.S. Cl. CPC H03M 1/66

(57) ABSTRACT

A multiplying digital-to-analog converter (MDAC) has first and second output terminals and first and second input terminals, which respectively receive a first signal and a second signal. The main components include four capacitors, an analog-to-digital converter (including a fifth capacitor), a reference voltage generation circuit, an amplifier, and multiple switches. Each capacitor is connected according to nodes. The inverting and non-inverting inputs of the amplifier are respectively connected to the corresponding nodes, and the outputs are connected to the first and second output terminals. In a sampling phase, the first and second capacitors respectively sample the input signals, and one end of the fifth capacitor has a voltage substantially equal to the voltage at the related node. In an amplification phase, the MDAC performs an amplification operation and outputs the corresponding signals.

### BACKGROUND OF THE INVENTION

### 1. Field of the Invention

The present invention generally relates to a pipeline analog-to-digital converter (pipeline ADC, also referred to as a pipelined ADC), and more particularly, to a multiplying digital-to-analog converter (MDAC) of the pipeline ADC.

### 2. Description of Related Art

Reference is made to FIG. 1, which is a circuit diagram of a conventional MDAC. The MDAC is commonly used in pipeline ADCs. The MDAC 100 has an input terminal INp, an input terminal INn, an output terminal OUTp, and an output terminal OUTn, and includes a sub-analog-to-digital converter (sub-ADC) 110, a reference voltage generation circuit 120, an operational amplifier 130, a switch SWp1, a switch SWp2, a switch SWp3, a switch SWp4, a switch SWp5, a switch SWn1, a switch SWn2, a switch SWn3, a switch SWn4, a switch SWn5, a capacitor Cp1, a capacitor Cp2, a capacitor Cn1, and a capacitor Cn2. The MDAC 100 performs a sampling operation and an amplification operation on an input signal Vip and an input signal Vin, and then outputs an output signal Vop and an output signal Von. The operating principle of the MDAC 100 is well known to people having ordinary skill in the art, so further elaboration is omitted for brevity. Vcm is a direct current (DC) voltage.

The sub-ADC 110 is designed to generate a digital code Dp (a digital code Dn) based on the terminal voltage of the capacitor Cp1 (the capacitor Cp2), and the reference voltage generation circuit 120 then provides a corresponding reference voltage Vrp (a reference voltage Vrn) to the capacitor Cp1 (the capacitor Cn1) according to the digital code Dp (the digital code Dn). In other words, the reference voltage Vrp (the reference voltage Vrn) is closely related to the terminal voltage of the capacitor Cp1 (the capacitor Cn1). However, the first sampling path (between the input terminal INp and the capacitor Cp1 or between the input terminal INn and the capacitor Cn1) and the second sampling path (between the input terminal INp and the sub-ADC 110 or between the input terminal INn and the sub-ADC 110) have random or systematic mismatches in resistance values and capacitance values. This causes the digital code Dp and the digital code Dn to fail to correctly reflect the terminal voltages of the capacitor Cp1 and the capacitor Cp2, thereby resulting in a reduction in the performance of the MDAC 100 or even causing an error.

### SUMMARY OF THE INVENTION

In view of the issues of the prior art, an object of the present invention is to provide an MDAC, so as to make an improvement to the prior art.

According to one aspect of the present invention, an MDAC is provided. The MDAC has a first input terminal, a second input terminal, a first output terminal, and a second output terminal. The first input terminal and the second input terminal respectively receive a first input signal and a second input signal. The MDAC includes a first capacitor, a second capacitor, a third capacitor, a fourth capacitor, an analog-to-digital converter (ADC), a reference voltage generation circuit, an amplifier, and multiple switches. The two terminals of the first capacitor are a first node and a second node, respectively. The two terminals of the second capacitor are a third node and a fourth node, respectively. The two terminals of the third capacitor are the second node and a fifth node, respectively. The two terminals of the fourth capacitor are the fourth node and a sixth node, respectively. The ADC includes a fifth capacitor and is configured to generate a digital code. The reference voltage generation circuit is coupled to the ADC and is configured to generate a reference voltage according to the digital code. The amplifier has an inverting input terminal, a non-inverting input terminal, an inverting output terminal, and a non-inverting output terminal. The inverting input terminal is coupled to the fourth node. The non-inverting input terminal is coupled to the second node. The inverting output terminal is coupled to the first output terminal. The non-inverting output terminal is coupled to the second output terminal. The switches are coupled to the first capacitor, the second capacitor, the third capacitor, the fourth capacitor, the ADC, the reference voltage generation circuit, and the amplifier. In a sampling phase, the first capacitor and the second capacitor respectively sample the first input signal and the second input signal. In an amplification phase, the MDAC performs an amplification operation to output a first output signal from the first output terminal and a second output signal from the second output terminal. In the sampling phase, a first voltage at a terminal of the fifth capacitor is substantially equal to a second voltage at the second node or the fourth node.

According to another aspect of the present invention, an MDAC is provided. The MDAC has a first input terminal, a second input terminal, a first output terminal, and a second output terminal. The first input terminal and the second input terminal respectively receive a first input signal and a second input signal. The MDAC includes: a first capacitor, a second capacitor, a third capacitor, a fourth capacitor, an analog-to-digital converter (ADC), a reference voltage generation circuit, an amplifier, and multiple switches. The two terminals of the first capacitor are a first node and a second node, respectively. The two terminals of the second capacitor are a third node and a fourth node, respectively. The two terminals of the third capacitor are the second node and a fifth node, respectively. The two terminals of the fourth capacitor are the fourth node and a sixth node, respectively. The ADC includes a fifth capacitor and is configured to generate a digital code. The reference voltage generation circuit is coupled to the ADC and is configured to generate a reference voltage according to the digital code. The amplifier has an inverting input terminal, a non-inverting input terminal, an inverting output terminal, and a non-inverting output terminal. The inverting input terminal is coupled to the fourth node. The non-inverting input terminal is coupled to the second node. The inverting output terminal is coupled to the first output terminal. The non-inverting output terminal is coupled to the second output terminal. The switches are coupled to the first capacitor, the second capacitor, the third capacitor, the fourth capacitor, the ADC, the reference voltage generation circuit, and the amplifier. In a sampling phase, the first capacitor and the second capacitor respectively sample the first input signal and the second input signal. In an amplification phase, the MDAC performs an amplification operation to output a first output signal from the first output terminal and a second output signal from the second output terminal. In the sampling phase, the first capacitor or the second capacitor samples the first input signal or the second input signal earlier than the fifth capacitor.

According to still another aspect of the present invention, an MDAC is provided. The MDAC has a first input terminal, a second input terminal, a first output terminal, and a second output terminal. The first input terminal and the second input terminal respectively receive a first input signal and a second input signal. The MDAC includes a first capacitor, a second capacitor, a third capacitor, a fourth capacitor, an analog-to-digital converter (ADC), a reference voltage generation circuit, an amplifier, a first switch, a second switch, and a third switch. The two terminals of the first capacitor are a first node and a second node, respectively. The two terminals of the second capacitor are a third node and a fourth node, respectively. The two terminals of the third capacitor are the second node and a fifth node, respectively. The two terminals of the fourth capacitor are the fourth node and a sixth node, respectively. The ADC includes a fifth capacitor and is configured to generate a digital code. The reference voltage generation circuit is coupled to the ADC and is configured to generate a reference voltage according to the digital code. The amplifier has an inverting input terminal, a non-inverting input terminal, an inverting output terminal, and a non-inverting output terminal. The inverting input terminal is coupled to the fourth node. The non-inverting input terminal is coupled to the second node. The inverting output terminal is coupled to the first output terminal. The non-inverting output terminal is coupled to the second output terminal. The first switch is coupled between the first input terminal and the first capacitor. The second switch is coupled between the second input terminal and the second capacitor. The third switch is coupled between a terminal of the fifth capacitor and the first node or the third node. In a sampling phase, the first capacitor and the second capacitor respectively sample the first input signal and the second input signal. In an amplification phase, the MDAC performs an amplification operation to output a first output signal and a second output signal from the first output terminal and the second output terminal, respectively. The first switch and the second switch change from an OFF state to an ON state when the sampling phase begins, while the third switch changes from the OFF state to the ON state after the sampling phase has begun.

The technical means embodied in the embodiments of the present invention can solve at least one of the problems of the prior art. Therefore, compared to the prior art, the present invention can improve the performance and reduce errors.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is the circuit diagram of a conventional MDAC.

FIG. 2 is the circuit diagram of an MDAC according to an embodiment of the present invention.

FIG. 3 is the circuit diagram of the sub-ADC according to an embodiment of the present invention.

FIG. 4 shows the waveforms of multiple clocks according to an embodiment of the present invention.

FIG. 5 shows the waveforms of multiple clocks according to another embodiment of the present invention.

FIG. 6 shows the waveforms of multiple clocks according to another embodiment of the present invention.

FIG. 7 shows the waveforms of multiple clocks according to another embodiment of the present invention.

FIG. 8 is the circuit diagram of an MDAC according to an embodiment of the present invention.

FIG. 9 is the circuit diagram of an MDAC according to an embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an MDAC. On account of that some or all elements of the MDAC could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

In the following description, signals are active-high, which means that signals are active at high levels and inactive at low levels, and that asserting/de-asserting a signal means setting the signal high/low. This is for the purpose of explanation, not for limiting the scope of the invention. In other words, in an alternative implementation, signals can be active-low, which means that signals are active at low levels and inactive at high levels, and that asserting/de-asserting a signal means setting the signal low/high. A level transition or a logic level transition means that a signal changes from an asserted (active) state to a de-asserted (inactive) state, or from a de-asserted (inactive) state to an asserted (active) state.

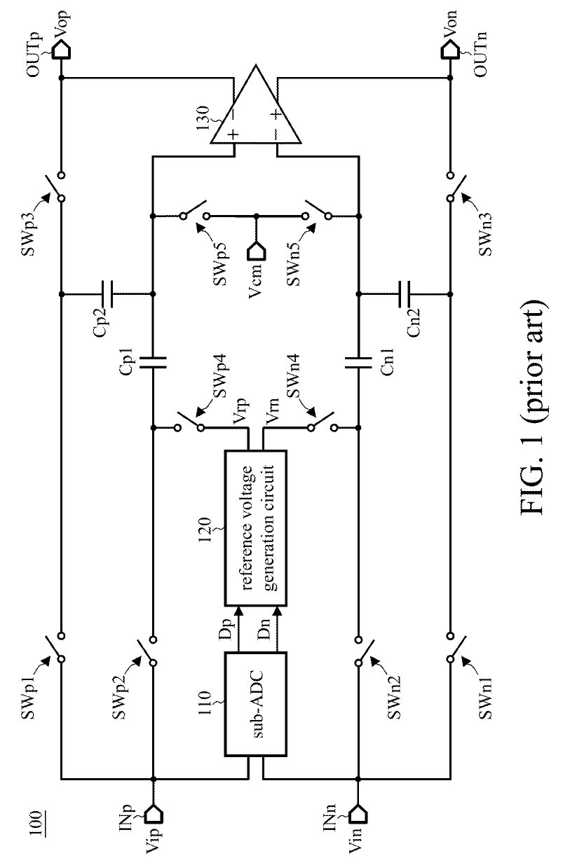

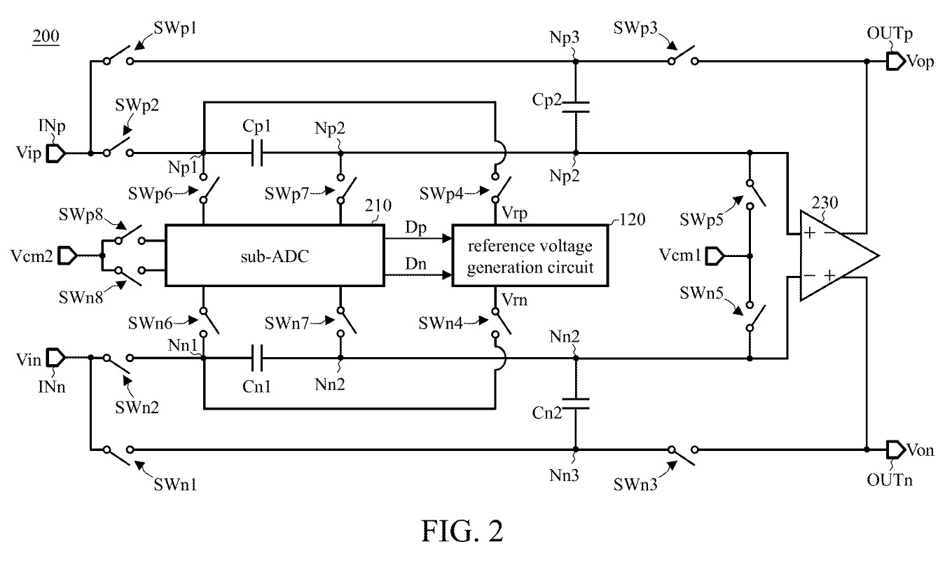

Reference is made to FIG. 2, which is a circuit diagram of an MDAC 200 according to an embodiment of the present invention. The MDAC 200 has the input terminal INp, the input terminal INn, the output terminal OUTp, and the output terminal OUTn, and includes a sub-ADC 210, the reference voltage generation circuit 120, an amplifier 230 (e.g., an operational amplifier), the capacitor Cp1, the capacitor Cp2, the capacitor Cn1, the capacitor Cn2, the switches SWp1 to SWp8, and the switches SWn1 to SWn8. The input terminal INp and the input terminal INn respectively receive the input signal Vip and the input signal Vin. The reference voltage generation circuit 120 in FIG. 2 is the same as the reference voltage generation circuit 120 in FIG. 1.

The two terminals of the capacitor Cp1 are the node Np1 and the node Np2, respectively. The two terminals of the capacitor Cp2 are the node Np2 and the node Np3, respectively. The two terminals of the capacitor Cn1 are the node Nn1 and the node Nn2, respectively. The two terminals of the capacitor Cn2 are the node Nn2 and the node Nn3, respectively.

The non-inverting input terminal of the amplifier 230 is coupled or electrically connected to the node Np2; the inverting input terminal of the amplifier 230 is coupled or electrically connected to the node Nn2; the inverting output terminal of the amplifier 230 is coupled or electrically connected to the output terminal OUTp; the non-inverting output terminal of the amplifier 230 is coupled or electrically connected to the output terminal OUTn.

One terminal of the switch SWp1 (SWn1) is coupled or electrically connected to the input terminal INp (INn); another terminal of the switch SWp1 (SWn1) is coupled or electrically connected to the node Np3 (Nn3).

One terminal of the switch SWp2 (SWn2) is coupled or electrically connected to the input terminal INp (INn); another terminal of the switch SWp2 (SWn2) is coupled or electrically connected to the node Np1 (Nn1).

One terminal of the switch SWp3 (SWn3) is coupled or electrically connected to the node Np3 (Nn3); another terminal of the switch SWp3 (SWn3) is coupled or electrically connected to the output terminal OUTp (OUTn).

One terminal of the switch SWp4 (SWn4) is coupled or electrically connected to the reference voltage generation circuit 120; another terminal of the switch SWp4 (SWn4) is coupled or electrically connected to the node Np1 (Nn1).

One terminal of the switch SWp5 (SWn5) receives the DC voltage Vcm1; another terminal of the switch SWp5 (SWn5) is coupled or electrically connected to the node Np2 (Nn2).

One terminal of the switch SWp6 (SWn6) is coupled or electrically connected to the sub-ADC 210; another terminal of the switch SWp6 (SWn6) is coupled or electrically connected to the node Np1 (Nn1).

One terminal of the switch SWp7 (SWn7) is coupled or electrically connected to the sub-ADC 210; another terminal of the switch SWp7 (SWn7) is coupled or electrically connected to the node Np2 (Nn2).

One terminal of the switch SWp8 (SWn8) is coupled or electrically connected to the sub-ADC 210; another terminal of the switch SWp8 (SWn8) receives the DC voltage Vcm2.

The DC voltage Vcm1 can be equal to or not equal to the DC voltage Vcm2. In some embodiments, the input signal Vip and the input signal Vin are a differential signal pair, the output signal Vop and the output signal Von are a differential signal pair, and the DC voltage Vcm1 and the DC voltage Vcm2 are the common mode voltage of the input signal Vip and the input signal Vin and/or the common mode voltage of the output signal Vop and the output signal Von.

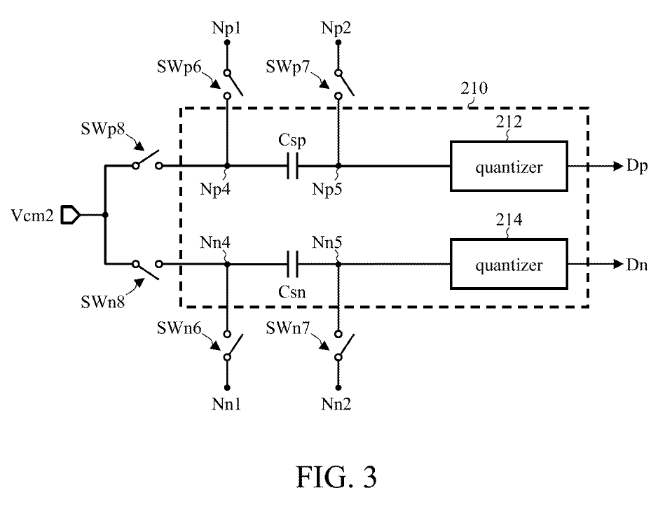

Reference is made to FIG. 3, which is a circuit diagram of the sub-ADC 210 according to an embodiment of the present invention. The sub-ADC 210 includes a capacitor Csp, a capacitor Csn, a quantizer 212, and a quantizer 214. The sub-ADC 210 is used to generate the digital codes Dp and Dn. The reference voltage generation circuit 120 can generate the reference voltage Vrp (the reference voltage Vrn) according to the digital code Dp (the digital code Dn).

The two terminals of the capacitor Csp are the node Np4 and the node Np5, respectively. The two terminals of the capacitor Csn are the node Nn4 and the node Nn5, respectively.

One terminal of the switch SWp6 is coupled or electrically connected to the node Np4. One terminal of the switch SWp7 is coupled or electrically connected to the node Np5. One terminal of the switch SWp8 is coupled or electrically connected to the node Np4.

One terminal of the switch SWn6 is coupled or electrically connected to the node Nn4. One terminal of the switch SWn7 is coupled or electrically connected to the node Nn5. One terminal of the switch SWn8 is coupled or electrically connected to the node Nn4.

When the switch SWp6 (SWn6) is turned on, the voltage at the node Np4 (Nn4) is substantially equal to the voltage at the node Np1 (Nn1). When the switch SWp7 (SWn7) is turned on, the voltage at the node Np5 (Nn5) is substantially equal to the voltage at the node Np2 (Nn2).

The input terminal of the quantizer 212 and the input terminal of the quantizer 214 are the node Np5 and the node Nn5, respectively. The node Np4 is not an input terminal of the quantizer 212. The node Nn4 is not an input terminal of the quantizer 214.

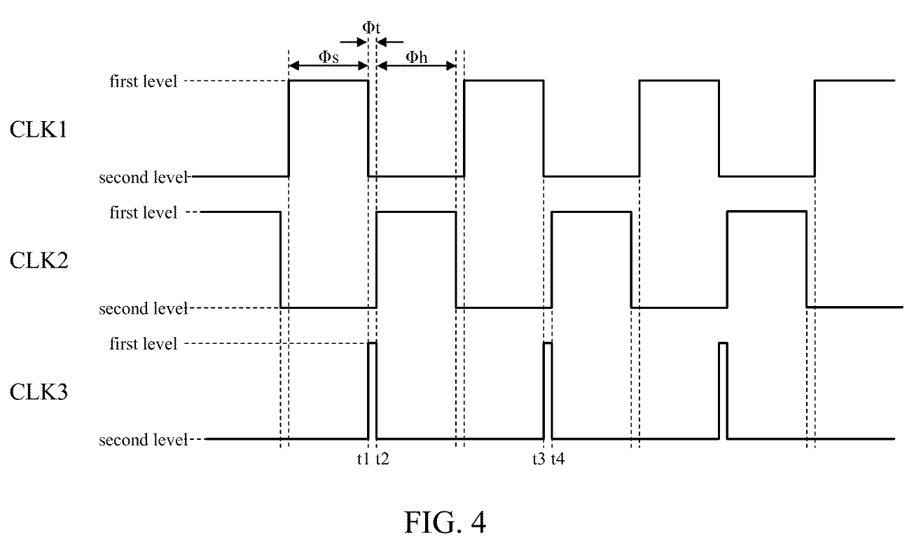

Reference is made to FIG. 4, which shows the waveforms of multiple clocks according to an embodiment of the present invention. The MDAC 200 operates according to the clock CLK1, the clock CLK2, and the clock CLK3 shown in FIG. 4. Between the falling edge of the clock CLK1 and the rising edge of the clock CLK2 (e.g., between the time point t1 and the time point t2, between the time point t3 and the time point t4, …), the clock CLK3 is at a first level (e.g., a high level). The clock CLK3 is at a second level (e.g., a low level) at other times.

When the clock CLK1 is at the first level, the MDAC 200 operates in the sampling phase Φs. In the sampling phase Φs, the switch SWp1, the switch SWn1, the switch SWp2, the switch SWn2, the switch SWp5, the switch SWn5, the switch SWp6, the switch SWn6, the switch SWp7, and the switch SWn7 are turned on, while the other switches are turned off, so that the capacitor Cp1 and the capacitor Cp2 sample the input signal Vip, and the capacitor Cn1 and the capacitor Cn2 sample the input signal Vin. When the clock CLK1 is at the second level (i.e., when the sampling phase Φs ends), the switch SWp1, the switch SWn1, the switch SWp2, the switch SWn2, the switch SWp5, the switch SWn5, the switch SWp6, the switch SWn6, the switch SWp7, and the switch SWn7 are turned off.

When the clock CLK2 is at the first level, the MDAC 200 operates in an amplification phase Φh. In the amplification phase Φh, the switch SWp3, the switch SWn3, the switch SWp4, and the switch SWn4 are turned on, while the other switches are turned off, so that the MDAC 200 performs an amplification operation to output the output signal Vop and the output signal Von from the output terminal OUTp and the output terminal OUTn, respectively. When the clock CLK2 is at the second level (i.e., when the amplification phase Φh ends), the switch SWp3, the switch SWn3, the switch SWp4, and the switch SWn4 are turned off.

When the clock CLK3 is at the first level, the MDAC 200 operates in a latch phase Φt. In the latch phase Φt, the switch SWp8 and the switch SWn8 are turned on, while the other switches are turned off, so that the quantizer 212 quantizes the voltage across the capacitor Csp (which is substantially equal to the voltage across the capacitor Cp1) to generate the digital code Dp, and the quantizer 214 quantizes the voltage across the capacitor Csn (which is substantially equal to the voltage across the capacitor Cn1) to generate the digital code Dn. In other words, since the voltage across the capacitor Csp (the capacitor Csn) is substantially equal to the voltage across the capacitor Cp1 (the capacitor Cn1), the quantizer 212 (the quantizer 214) substantially generates the digital code Dp (the digital code Dn) according to the terminal voltage of the capacitor Cp1 (the capacitor Cn1).

It can be observed that because the sub-ADC 210 substantially quantizes the voltage across the capacitor Cp1 (or its terminal voltage) and the voltage across the capacitor Cn1 (or its terminal voltage), the digital code Dp and the digital code Dn can correctly reflect the terminal voltages of the capacitor Cp1 and the capacitor Cn1. In other words, the issue of impedance mismatch between paths occurring in the MDAC 100 does not occur in the MDAC 200.

Since the capacitance value of the capacitor Csp (the capacitor Csn) is smaller than the capacitance value of the capacitor Cp1 (the capacitor Cn1), the above operation does not significantly change the stable behavior of the terminal voltages of the capacitor Cp1 (the capacitor Cn1).

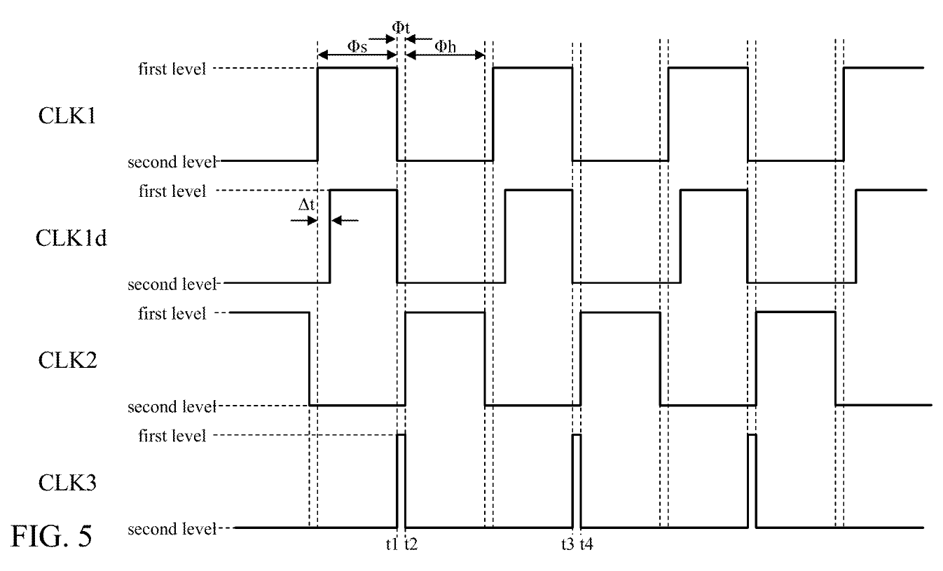

Reference is made to FIG. 5, which shows the waveforms of multiple clocks according to another embodiment of the present invention. The rising edge of the clock CLK1d lags behind the rising edge of the clock CLK1 by a time difference Δt, and the falling edge of the clock CLK1d aligns with the falling edge of the clock CLK1. In this embodiment, the switch SWp6, the switch SWn6, the switch SWp7, and the switch SWn7 operate according to the clock CLK1d. That is to say, the switch SWp6, the switch SWn6, the switch SWp7, and the switch SWn7 change from the OFF state to the ON state after the sampling phase Φs begins, so that the capacitor Cp1 and the capacitor Cn1 sample the input signal Vip or the input signal Vin before the capacitor Csp and the capacitor Csn. Such operation can ensure that after the terminal voltages of the capacitor Cp1 and the capacitor Cp2 become more stable, the capacitor Csp and the capacitor Csn are respectively connected in parallel with the capacitor Cp1 and the capacitor Cn1.

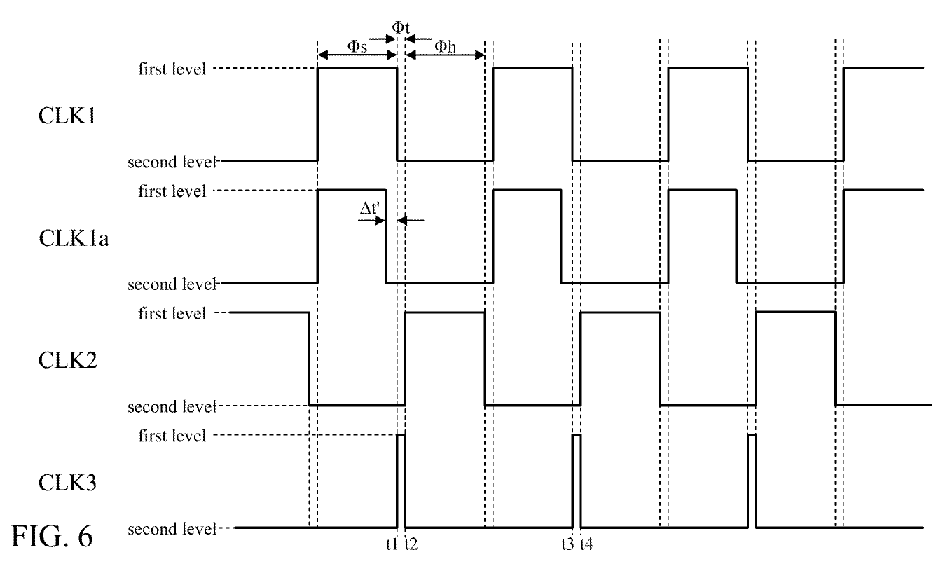

Reference is made to FIG. 6, which shows the waveforms of multiple clocks according to another embodiment of the present invention. The rising edge of the clock CLK1a aligns with the rising edge of the clock CLK1, but the falling edge of the clock CLK1a precedes the falling edge of the clock CLK1 by a time difference Δt'. The switch SWp1, the switch SWn1, the switch SWp2, the switch SWn2, the switch SWp6, and the switch SWn6 operate according to the clock CLK1, while the switch SWp5, the switch SWn5, the switch SWp7, and the switch SWn7 operate according to the clock CLK1a. In other words, the time point at which the switch SWp5, the switch SWn5, the switch SWp7, and the switch SWn7 change from the ON state to the OFF state is earlier than the time point at which the switch SWp1, the switch SWn1, the switch SWp2, the switch SWn2, the switch SWp6, and the switch SWn6 change from the ON state to the OFF state (corresponding to the end of the sampling phase Φs, for example, the time point t1 or the time point t3). Such design can improve the stability of the circuit.

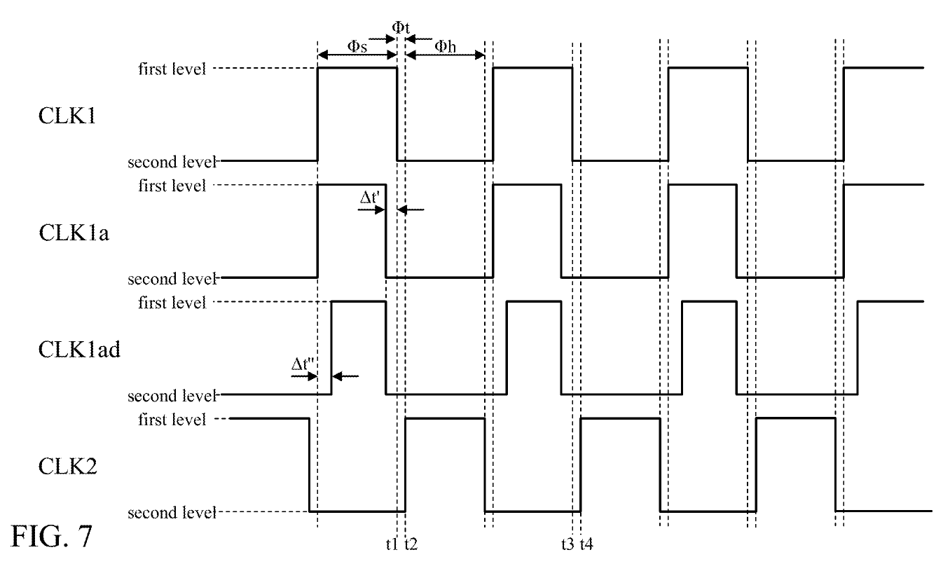

Reference is made to FIG. 7, which shows the waveforms of multiple clocks (note that the clock CLK3 is omitted in FIG. 7) according to another embodiment of the present invention. The falling edge of the clock CLK1ad aligns with the falling edge of the clock CLK1a, but the rising edge of the clock CLK1ad lags behind the rising edge of the clock CLK1a by a time difference Δt''. The switch SWp1, the switch SWn1, the switch SWp2, the switch SWn2, the switch SWp6, and the switch SWn6 operate according to the clock CLK1; the switch SWp5 and the switch SWn5 operate according to the clock CLK1a; and the switch SWp7 and the switch SWn7 operate according to the clock CLK1ad. In other words, the time point at which the switch SWp1, the switch SWn1, the switch SWp2, the switch SWn2, the switch SWp6, the switch SWn6, the switch SWp5, and the switch SWn5 change from the OFF state to the ON state is earlier than the time point at which the switch SWp7 and the switch SWn7 change from the OFF state to the ON state.

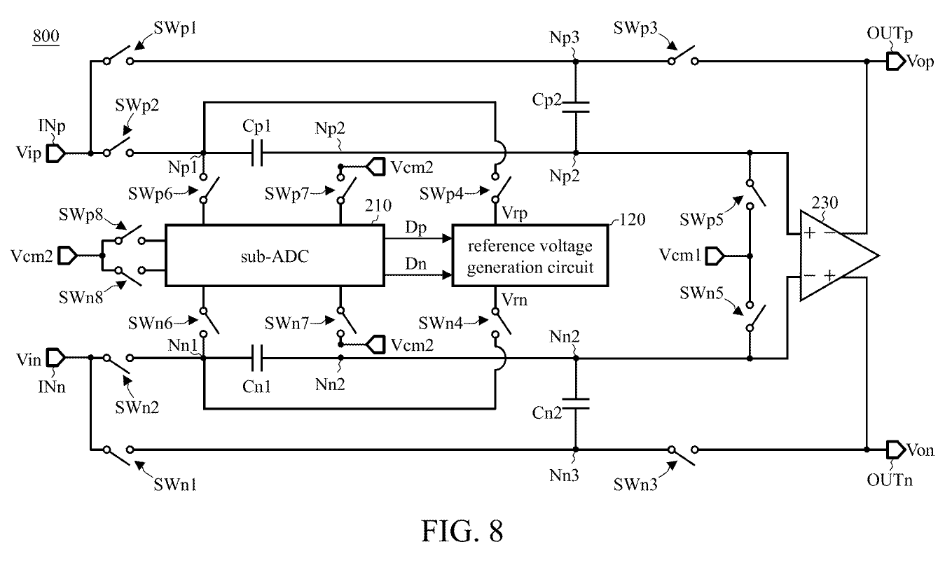

Reference is made to FIG. 8, which is the circuit diagram of an MDAC 800 according to an embodiment of the present invention. The MDAC 800 is similar to the MDAC 200, except that one terminal of the switch SWp7 (SWn7) is not coupled or electrically connected to the node Np2 (Nn2), but instead receives the DC voltage Vcm2. In the embodiment of FIG. 8, the switch SWp7 and the switch SWp5 are turned on or turned off at substantially the same time, while the switch SWn7 and the switch SWn5 are turned on or turned off at substantially the same time. For example, the switch SWp5, the switch SWn5, the switch SWp7, and the switch SWn7 all operate according to the clock CLK1 or the clock CLK1a.

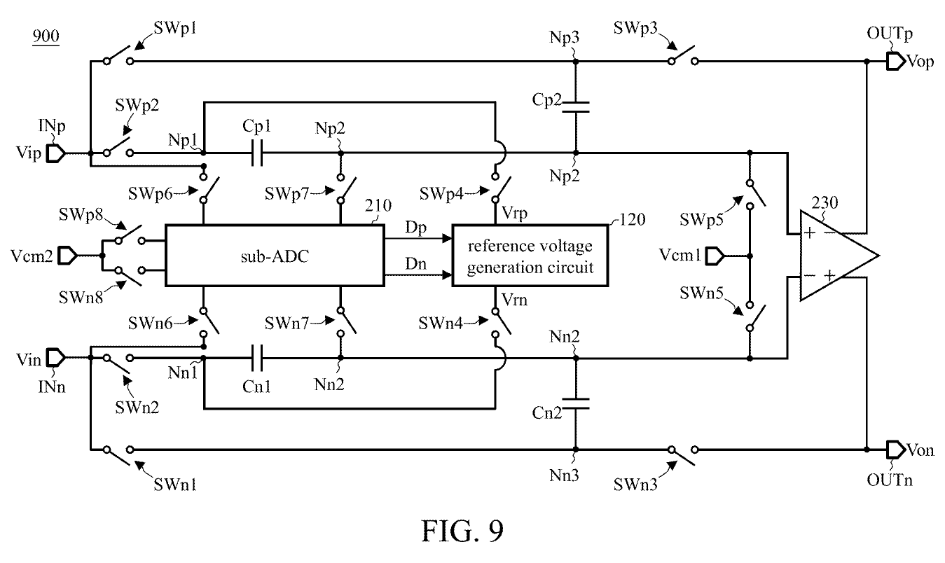

Reference is made to FIG. 9, which is the circuit diagram of an MDAC 900 according to an embodiment of the present invention. The MDAC 900 is similar to the MDAC 200, except that one terminal of the switch SWp6 (SWn6) is not coupled or electrically connected to the node Np1 (Nn1), but instead receives the input signal Vip (Vin). In the embodiment of FIG. 9, the switch SWp6 and the switch SWn6 operate according to the clock CLK1 or the clock CLK1d.

In the embodiments of FIG. 8 and FIG. 9, because the terminal voltages of the capacitor Csp and the capacitor Csn can still appropriately reflect at least one terminal voltage of the capacitor Cp1 or the capacitor Cn1, the MDAC 800 and the MDAC 900 can still avoid the issues encountered in the prior art.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A multiplying digital-to-analog converter (MDAC), having a first input terminal, a second input terminal, a first output terminal, and a second output terminal, the first input terminal and the second input terminal respectively receiving a first input signal and a second input signal, the MDAC comprising:
a first capacitor, wherein two terminals of the first capacitor are a first node and a second node, respectively;
a second capacitor, wherein two terminals of the second capacitor are a third node and a fourth node, respectively;
a third capacitor, wherein two terminals of the third capacitor are the second node and a fifth node, respectively;
a fourth capacitor, wherein two terminals of the fourth capacitor are the fourth node and a sixth node, respectively;
an analog-to-digital converter (ADC) comprising a fifth capacitor and configured to generate a digital code;
a reference voltage generation circuit coupled to the ADC and configured to generate a reference voltage according to the digital code;
an amplifier having an inverting input terminal, a non-inverting input terminal, an inverting output terminal, and a non-inverting output terminal, wherein the inverting input terminal is coupled to the fourth node, the non-inverting input terminal is coupled to the second node, the inverting output terminal is coupled to the first output terminal, and the non-inverting output terminal is coupled to the second output terminal; and
a plurality of switches coupled to the first capacitor, the second capacitor, the third capacitor, the fourth capacitor, the ADC, the reference voltage generation circuit, and the amplifier;
wherein in a sampling phase, the first capacitor and the second capacitor sample the first input signal and the second input signal, respectively; in an amplification phase, the MDAC performs an amplification operation to output a first output signal from the first output terminal and a second output signal from the second output terminal; and, in the sampling phase, a first voltage at a terminal of the fifth capacitor is substantially equal to a second voltage at the second node or the fourth node.

2. The MDAC of claim 1, wherein the plurality of switches comprises:
a first switch coupled between the first input terminal and the first capacitor;
a second switch coupled between the second input terminal and the second capacitor; and
a third switch coupled between the terminal of the fifth capacitor and the second node or the fourth node;
wherein the first switch and the second switch change from an ON state to an OFF state when the sampling phase ends, while the third switch changes from the ON state to the OFF state before the sampling phase ends.

3. The MDAC of claim 1, wherein in the sampling phase, the first capacitor or the second capacitor samples the first input signal or the second input signal earlier than the fifth capacitor.

4. The MDAC of claim 1, wherein the plurality of switches comprises:
a first switch coupled between the first input terminal and the first capacitor;
a second switch coupled between the second input terminal and the second capacitor; and
a third switch coupled between another terminal of the fifth capacitor and the first node or the third node;
wherein the first switch and the second switch change from an OFF state to an ON state when the sampling phase begins, while the third switch changes from the OFF state to the ON state after the sampling phase has begun.

5. The MDAC of claim 4, wherein the ADC further comprises:
a quantizer coupled to the fifth capacitor and configured to generate the digital code;
wherein the other terminal is not an input terminal of the quantizer.

6. The MDAC of claim 1 further comprising:
a switch coupled to another terminal of the fifth capacitor and a direct current (DC) voltage;
wherein between the sampling phase and the amplification phase, the switch is turned on and the ADC generates the digital code.

7. The MDAC of claim 6, wherein the ADC further comprises:
a quantizer coupled to the fifth capacitor and configured to generate the digital code;
wherein the other terminal is not an input terminal of the quantizer.

8. The MDAC of claim 1, wherein the ADC further comprises:
a quantizer coupled to the fifth capacitor and configured to generate the digital code;
wherein the terminal is an input terminal of the quantizer.

9. A multiplying digital-to-analog converter (MDAC), having a first input terminal, a second input terminal, a first output terminal, and a second output terminal, the first input terminal and the second input terminal respectively receiving a first input signal and a second input signal, the MDAC comprising:
a first capacitor, wherein two terminals of the first capacitor are a first node and a second node, respectively;
a second capacitor, wherein two terminals of the second capacitor are a third node and a fourth node, respectively;
a third capacitor, wherein two terminals of the third capacitor are the second node and a fifth node, respectively;
a fourth capacitor, wherein two terminals of the fourth capacitor are the fourth node and a sixth node, respectively;
an analog-to-digital converter (ADC) comprising a fifth capacitor and configured to generate a digital code;
a reference voltage generation circuit coupled to the ADC and configured to generate a reference voltage according to the digital code;
an amplifier having an inverting input terminal, a non-inverting input terminal, an inverting output terminal, and a non-inverting output terminal, wherein the inverting input terminal is coupled to the fourth node, the non-inverting input terminal is coupled to the second node, the inverting output terminal is coupled to the first output terminal, and the non-inverting output terminal is coupled to the second output terminal; and
a plurality of switches coupled to the first capacitor, the second capacitor, the third capacitor, the fourth capacitor, the ADC, the reference voltage generation circuit, and the amplifier;
wherein in a sampling phase, the first capacitor and the second capacitor sample the first input signal and the second input signal, respectively; in an amplification phase, the MDAC performs an amplification operation to output a first output signal from the first output terminal and a second output signal from the second output terminal; and, in the sampling phase, the first capacitor or the second capacitor samples the first input signal or the second input signal earlier than the fifth capacitor.

10. The MDAC of claim 9, wherein in the sampling phase, a first voltage at a terminal of the fifth capacitor is substantially equal to a second voltage at the second node or the fourth node.

11. The MDAC of claim 10, wherein the plurality of switches comprises:
a first switch coupled between the first input terminal and the first capacitor;
a second switch coupled between the second input terminal and the second capacitor; and
a third switch coupled between the terminal of the fifth capacitor and the second node or the fourth node;
wherein the first switch and the second switch change from an ON state to an OFF state when the sampling phase ends, while the third switch changes from the ON state to the OFF state before the sampling phase ends.

12. The MDAC of claim 9 further comprising:
a switch coupled between a terminal of the fifth capacitor and a direct current (DC) voltage;
wherein between the sampling phase and the amplification phase, the switch is turned on and the ADC generates the digital code.

13. The MDAC of claim 12, wherein the ADC further comprises:
a quantizer coupled to the fifth capacitor and configured to generate the digital code;
wherein the terminal is not an input terminal of the quantizer.

14. A multiplying digital-to-analog converter (MDAC), having a first input terminal, a second input terminal, a first output terminal, and a second output terminal, the first input terminal and the second input terminal respectively receiving a first input signal and a second input signal, the MDAC comprising:
a first capacitor, wherein two terminals of the first capacitor are a first node and a second node, respectively;
a second capacitor, wherein two terminals of the second capacitor are a third node and a fourth node, respectively;
a third capacitor, wherein two terminals of the third capacitor are the second node and a fifth node, respectively;
a fourth capacitor, wherein two terminals of the fourth capacitor are the fourth node and a sixth node, respectively;
an analog-to-digital converter (ADC) comprising a fifth capacitor and configured to generate a digital code;
a reference voltage generation circuit coupled to the ADC and configured to generate a reference voltage according to the digital code;
an amplifier having an inverting input terminal, a non-inverting input terminal, an inverting output terminal, and a non-inverting output terminal, wherein the inverting input terminal is coupled to the fourth node, the non-inverting input terminal is coupled to the second node, the inverting output terminal is coupled to the first output terminal, and the non-inverting output terminal is coupled to the second output terminal;
a first switch coupled between the first input terminal and the first capacitor;
a second switch coupled between the second input terminal and the second capacitor; and
a third switch coupled between a terminal of the fifth capacitor and the first node or the third node;
wherein in a sampling phase, the first capacitor and the second capacitor sample the first input signal and the second input signal, respectively; and, in an amplification phase, the MDAC performs an amplification operation to output a first output signal and a second output signal from the first output terminal and the second output terminal, respectively;
wherein the first switch and the second switch change from an OFF state to an ON state when the sampling phase begins, while the third switch changes from the OFF state to the ON state after the sampling phase has begun.

15. The MDAC of claim 14, wherein the ADC further comprises:
a quantizer coupled to the fifth capacitor and configured to generate the digital code;
wherein the terminal is not an input terminal of the quantizer.

16. The MDAC of claim 14, wherein the terminal is a first terminal of the fifth capacitor; in the sampling phase, a first voltage at a second terminal of the fifth capacitor is substantially equal to a second voltage at the second node or the fourth node.

17. The MDAC of claim 16 further comprising:
a fourth switch coupled between the second terminal of the fifth capacitor and the second node or the fourth node;
wherein the first switch and the second switch change from the ON state to the OFF state when the sampling phase ends, and the fourth switch changes from the ON state to the OFF state before the sampling phase ends.

18. The MDAC of claim 14 further comprising:
a fourth switch coupled between the terminal of the fifth capacitor and a direct current (DC) voltage;
wherein between the sampling phase and the amplification phase, the fourth switch is turned on and the ADC generates the digital code.

19. The MDAC of claim 18, wherein the ADC further comprises:
a quantizer coupled to the fifth capacitor and configured to generate the digital code;
wherein the terminal is not an input terminal of the quantizer.
